(19) United States
(12) Patent Application Publication
(10) Pub. No.: US 2005/0199586 A1
(43) Pub. Date: Sep. 15, 2005

(54) Resist removal method and semiconductor device manufactured by using the same

(75) Inventors: Atsushi Matsushita, Isahaya-shi (JP); Isao Matsumoto, Nagaokakyo-shi (JP); Kazuaki Inukai, Hamamatsu-shi (JP); Hong Jae Shin, Seoul (KR); Naofumi Ohashi, Tokyo (JP); Shuji Sone, Tama-shi (JP); Kaori Misawa, Kaizu-gun (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Semiconductor Leading Edge Technologies, Inc., Tsukuba-shi (JP)

(21) Appl. No.: 11/052,911

(22) Filed: Feb. 9, 2005

(30) Foreign Application Priority Data
Mar. 12, 2004 (JP) 2004-070852

(51) Int. Cl. B44C 1/22; H01L 21/311

(52) U.S. Cl. 216/67; 438/725; 216/68

(57) ABSTRACT

In resist removal using hydrogen gas, the specific dielectric constant of an insulating film of a low dielectric constant can be reduced and the resist removal speed can be increased. A wafer is loaded on a rotary table in a chamber, and hydrogen mixed gas is introduced into a discharge tube from a gas introduction port, and a μ wave is supplied into the discharge tube via a waveguide, and the mixed gas is excited by plasma, and a hydrogen active species is generated. And, a neutral radical (hydrogen radical) of hydrogen atoms or hydrogen molecules is introduced into the chamber from a gas transport pipe and a resist mask on the surface of the wafer is removed. Here, by a substrate heating system for heating the rotary table and controlling the temperature, the temperature of the wafer is set within the range from 200° C. to 400° C. The processed gas after resist removal is ejected from the chamber through a gas ejection port by an exhaust system.

### BACKGROUND OF THE INVENTION

1. Field of the Invention

The present invention relates to a resist removal method and a semiconductor device manufactured by using it and more particularly to, when removing a resist film mask formed on an inter-layer insulating film composed of an insulating film material of a low dielectric constant, a resist removal method capable of preventing the dielectric constant of the inter-layer insulating film from increasing and a semiconductor device manufactured by using the method.

2. Description of the Related Art

In manufacture of recent semiconductor devices, particularly super LSIs formed on silicon substrates, refinement of semiconductor device elements and multiplexing of wires connecting device elements are essential. And, in correspondence to realization of a low voltage and a high speed operation of semiconductor devices, realization of a low dielectric constant of inter-layer insulating films between multilayer wires is necessary. Particularly, in semiconductor devices of a logic system, a resistance increase due to fine wires and an increase in the parasitic capacity between wires cause a reduction in the operation speed of the semiconductor devices, so that multilayer wires applying an insulating film material of a low dielectric constant to inter-layer insulating films are essential. Here, an insulating film of a low dielectric constant is referred to as an insulating film of a specific dielectric constant of 4 or less of a silicon dioxide film.

As such an insulating film of a low dielectric constant, there are an insulating film having a siloxane skeleton, an insulating film having a main skeleton of organic high polymer molecules, and furthermore an insulating film obtained by perforating those films. In the aforementioned insulating film having the siloxane skeleton, a silica film including at least one of the Si—CH3 bond, Si—H bond, and Si—F bond such as an insulating film of the silsesquioxane group and a silicon oxide film (SiOC film) containing carbon have a specific dielectric constant of 3 or less and in the insulating film having the main skeleton of organic high polymer molecules, the specific dielectric constant thereof is generally smaller than that of the insulating film having the siloxane skeleton, and SiLK (registered trademark) composed of an organic polymer is well known. Here, as an insulating material well known as an insulating film of the silsesquioxane group, there are methyl silsesquioxane (MSQ), hydrogen silsesquioxane (HSQ), and methylated hydrogen silsesquioxane (MHSQ). Further, when the aforementioned insulating films are perforated, the specific dielectric constant thereof can be easily changed to about 2 to 3.

However, when using these insulating films of a low dielectric constant as an inter-layer insulating film as mentioned above, they must be patterned. For example, forming of via holes for connecting between multilayer wires or forming of wiring trenches in an insulating film in trench-embedded wires (damascene wiring or dual damascene wiring) is required. Hereinafter, by referring to FIG. 7A-7D, the steps for forming a via hole in the aforementioned insulating films of a low dielectric constant will be roughly explained. Here, FIG. 7A-7D shows schematic cross sectional views in the order of forming steps of an inter-layer insulating film having a via hole of a semiconductor device.

As shown in FIG. 7A, on the surface of a silicon substrate 101, generally, via a thin silicon oxide film (not shown in the drawing), an MSQ film 102 is formed by the known spin-on coating method. And, using the known photolithographic art, on the surface of the MSQ film 102, a resist mask 104 having a resist opening 103 is formed.

Next, as shown in FIG. 7B, by reactive ion etching (RIE) utilizing the resist mask 104 as an etching mask, for example, using mixed gas of C4F8 and O2, the MSQ film 102 is dry-etched to form a via hole 105.

Then, the resist mask 104 is removed by the plasma process. Here, as shown in FIG. 7C, in the plasma process, by irradiation of plasma 106 of nitrogen (N2) or hydrogen (H2), the resist mask 104 is etched, and finally the resist is removed. And, as shown in FIG. 7D, an inter-layer insulating film 107 having the via hole 105 is formed on the silicon substrate 101. Hereafter, though not shown in the drawing, a conductor material (via plug) filled in the via hole 105 and a wire layer connected to it are formed.

The aforementioned removal of the resist mask 104 is executed by using a plasma processing apparatus as schematically shown in FIG. 8 (for example, refer to Patent Document 1). FIG. 8 is a schematic cross sectional view of the plasma processing apparatus by the capacitive coupling type plasma generation method generally used often.

A plasma processing device 200, as a basic constitution thereof, has, for example, a cylindrical chamber 210 composed of aluminum whose surface is anodized, a substrate support table 202 (lower electrode) attached to the bottom inside the chamber 201, an opposite electrode 203 (upper electrode) attached to the upper part inside the chamber 201, a high frequency power source 204 connected to the substrate support table 202, a gas feed system 205 for feeding raw gas for ashing into the chamber 201, and an exhaust system 206 for ejecting ashing gas after reaction from the chamber 201.

In the aforementioned removal of the resist mask 104 by the plasma process, a wafer 207, which is a silicon substrate, is loaded on the substrate support table 202, and nitrogen (N₂) or hydrogen (H₂) is introduced into the chamber 201 as raw gas for resist removal from a gas introduction port 208, and high frequency power, for example, of 13.56 MHz is applied from the high frequency power source 204, and the raw gas is plasma-excited. And, plasma PZ is generated in the chamber 201 and the resist mask on the wafer 207 is removed by the plasma etching process. Further, introduction of raw gas for resist removal may be executed via the so-called shower head attached to the upper electrode 203. The processing gas after etching reaction is ejected from the chamber 201 through a gas ejection port 209 by the exhaust system 206.

[Patent Document 1] Japanese Patent Application 2001-118830 (paragraphs [0013] to [0017], FIG. 1)

### SUMMARY OF THE INVENTION

### PROBLEMS TO BE SOLVED BY THE INVENTION

In manufacture of a semiconductor device, it is necessary to use a resist mask formed by the photolithographic art for an etching mask and finely pattern various insulator films, semiconductor films, or conductor films by the dry etching art. Further, it is also necessary to use the aforementioned resist mask for an ion implantation mask and dope various conductive impurities on the surface of a semiconductor substrate. And, after end of the aforementioned process, the prior art removes the aforementioned resist mask by plasma ashing mainly using the aforementioned plasma processing apparatus. Here, until now, as raw gas used for plasma ashing, mixed gas added with oxygen gas (O₂) or halogen compound gas has been used. However, when an insulating film of a low dielectric constant containing an organic component such as an MSQ film having a composition of [CH₃SiO_{3/2}]ₙ is used for an inter-layer insulating film, in plasma ashing using the aforementioned raw gas, the film quantity is changed after ashing and the specific dielectric constant thereof is increased. This will be explained by referring to FIG. 9A-9B. FIG. 9A-9B is a schematic structural diagram showing the situation that the MSQ film changes in quality due to ashing by oxygen plasma. In the aforementioned plasma ashing, when an active species of a strong oxidative effect such as oxygen ions or oxygen radical is plasma-irradiated on the surface of the MSQ film, the bond of Si—CH₃ shown in FIG. 9A is changed to the bond of Si—O as shown in FIG. 9B. In this way, the surface of the MSQ film is changed in composition, and a silicon dioxide (SiO₂) film is partially formed as a deteriorated layer, and the specific dielectric constant of the film is greatly increased. Film deterioration due to oxygen plasma ashing generally occurs in the aforementioned insulating film of a low dielectric constant.

Therefore, at present, as raw gas for resist removal by plasma, in place of oxygen gas, use of nitrogen gas, hydrogen gas, or mixed gas thereof has been studied eagerly. The inventors have studied in detail changes in the quality of an insulating film of a low dielectric constant in removal of the aforementioned resist mask using plasma by variously changing the aforementioned raw gas. Here, when using nitrogen gas as raw gas, it is found that the organic component such as the methyl group or ethyl group is replaced with nitrogen atoms and the specific dielectric constant of the film is increased slightly. Further, when hydrogen gas is used as raw gas, it is found that although the increase in the specific dielectric constant is suppressed, the resist removal speed is reduced unavoidably.

An effective method for avoiding the reduction in the resist removal speed is to increase the plasma density of hydrogen. However, when the plasma density is increased by using a conventional plasma processing apparatus, the specific dielectric constant of the inter-layer insulating film after removal of the resist mask is increased. Regarding the increase in the specific dielectric constant in this case, the increase degree becomes remarkable as the dielectric constant is reduced by increasing the organic component amount or increasing the porosity. As mentioned above, when hydrogen is used as raw gas for excitation of plasma in removal of the resist mask, compatibility of improvement of the resist removal speed with prevention of the specific dielectric constant of an insulating film of a low dielectric constant from increasing is now become obvious as a very difficult problem.

The present invention was developed with the foregoing in view and is intended to provide a resist removal apparatus and a resist removal method capable of realizing improvement of the resist removal speed and prevention of increase of the specific dielectric constant of an insulating film of a low dielectric constant and a semiconductor device manufactured by using them.

### MEANS FOR SOLVING THE PROBLEMS

The first invention is a resist removal method using a resist removal apparatus including a plasma generation unit of hydrogen gas, a processing chamber separated and installed so as to prevent hydrogen plasma generated by the plasma generation unit from irradiating a processed substrate, and an active species transport pipe for transporting a hydrogen active species generated by the plasma generation unit to the processing chamber, characterized in that a resist film formed on the processed substrate is removed by etching using mixed gas of hydrogen gas and inactive gas as raw gas.

The second invention is a resist removal method using a resist removal apparatus including a plasma generation unit of hydrogen gas, a processing chamber for loading a processed substrate installed in an integral structure with the plasma generation unit, and a shielding plate inserted between the plasma generation unit and the processed substrate so as to shield hydrogen plasma generated in the plasma generation unit, characterized in that a resist film formed on the processed substrate is removed by etching using mixed gas of hydrogen gas and inactive gas as raw gas.

The third invention is a resist removal apparatus for etching a resist film on a processed substrate using a hydrogen active species generated by plasma excitation of raw gas including hydrogen gas.
a resist removal method using a resist removal apparatus including a plasma generation unit of the hydrogen gas, a processing chamber separated and installed so as to prevent hydrogen plasma generated by the plasma generation unit from irradiating the processed substrate, and an active species transport pipe for transporting the hydrogen active species generated by the plasma generation unit to the processing chamber, and
a semiconductor device manufactured by using a resist removal method for removing a resist film, which is a resist mask used to pattern an insulating film of a low dielectric constant of a specific dielectric constant of 3 or less formed on the processed substrate, by etching using mixed gas of hydrogen gas and inactive gas as the aforementioned raw gas, wherein:
the insulating film of a low dielectric constant is an inter-layer insulating film of a multi-layer wiring structure for connecting between semiconductor device elements.

### BRIEF DESCRIPTION OF THE DRAWINGS

FIG. 1A-1D is cross sectional views of devices for each step showing the resist removal method in manufacture of semiconductor devices relating to the first embodiment of the present invention.

FIG. 2 is a schematic cross sectional view of the resist removal apparatus relating to the first embodiment of the present invention.

FIG. 3 is a structural diagram of an insulating film of a low dielectric constant for explaining the effects of the present invention.

FIG. 4A-4C is cross sectional views of devices for each step showing the resist removal method in manufacture of semiconductor devices relating to the second embodiment of the present invention.

FIG. 5A-5B is cross sectional views for each step following the steps shown in FIG. 4A-4C.

FIG. 6 is a schematic cross sectional view of the resist removal apparatus relating to the second embodiment of the present invention.

FIG. 7A-7D is cross sectional views of devices for each step showing the resist removal method in manufacture of semiconductor devices for explaining the prior art.

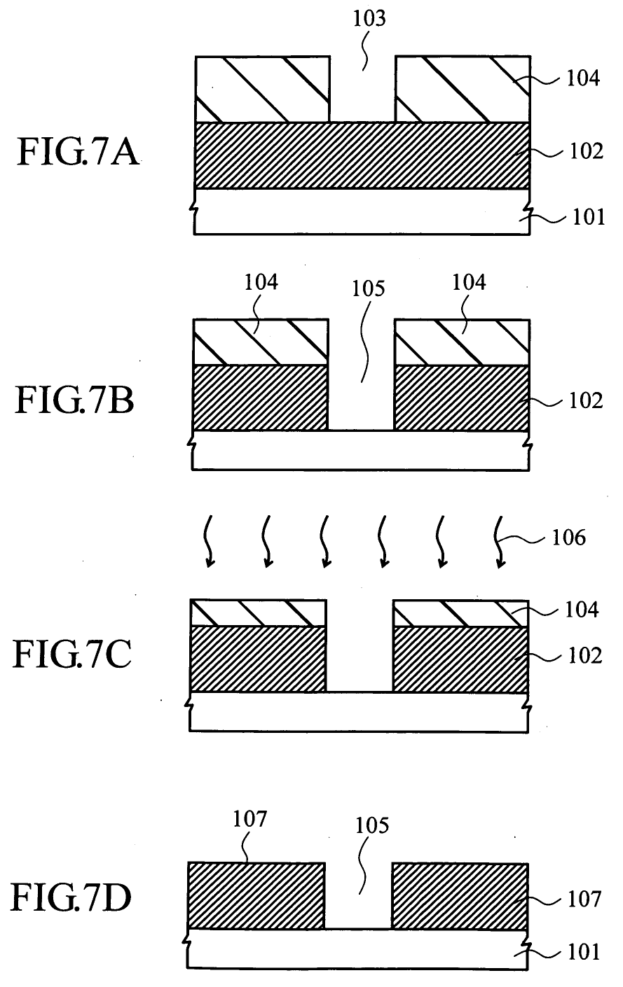

FIG. 8 is a schematic cross sectional view of the resist removal apparatus for explaining the prior art.

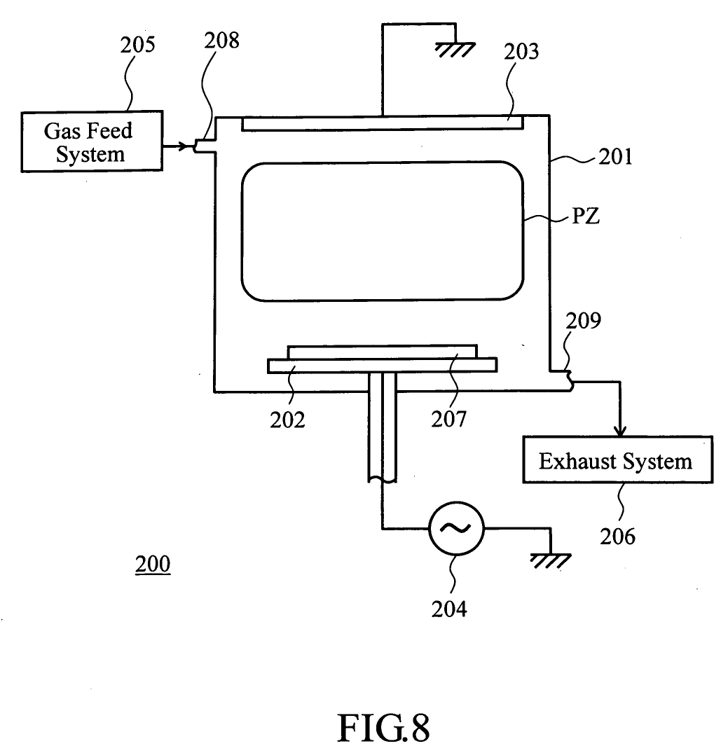

FIG. 9A-9B is a structural diagram of an insulating film of a low dielectric constant for explaining the prior art.

### DESCRIPTION OF THE PREFERRED EMBODIMENTS

Hereinafter, some of the embodiments of the present invention will be explained in detail with reference to the accompanying drawings.

### Embodiment 1

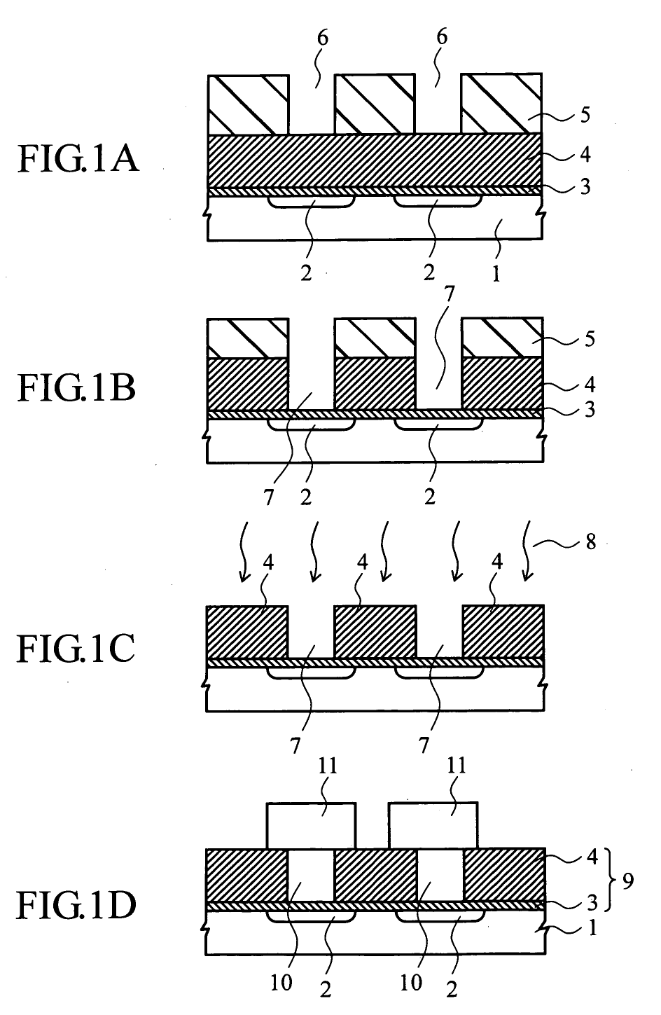

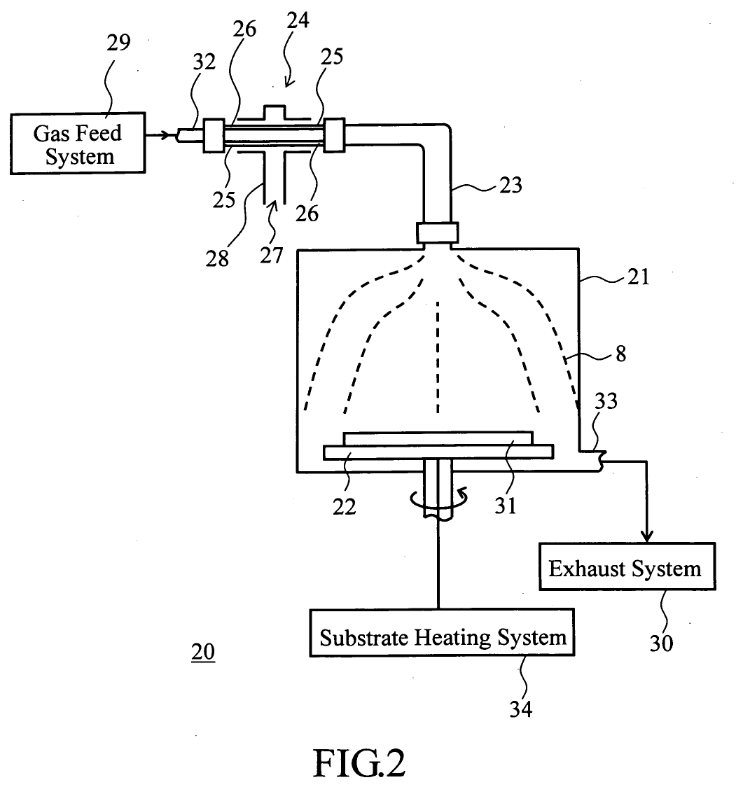

FIG. 1A-1D is cross sectional views of devices for each step showing manufacture of semiconductor devices to which the resist removal method relating to the first embodiment of the present invention is applied. FIG. 2 is a schematic cross sectional view of the resist removal apparatus used for resist removal.

On the surface of a p-conductive type silicon substrate 1, n-conductive type diffusion layers 2 are formed and on the surface of the silicon substrate 1, a silicon oxide film 3 with a thickness of, for example, 50 nm is formed by thermal oxidation. And, by using the known spin-on coating method for the silicon oxide film 3, an MSQ film 4 with a thickness of about 1 μm is formed and a resist mask 5 is formed on the MSQ film 4 by the photolithographic art. In this case, in the resist mask 5, resist openings 6 are formed (FIG. 1A).

Next, by dry etching by the RIE using the resist mask 5 as an etching mask, the MSQ film 4 and the silicon oxide film 3 are etched anisotropically and via holes (contact holes) 7 reaching the diffusion layers 2 are formed (FIG. 1B). Here, as raw gas for dry etching, for example, mixed gas of C₄F₈ and O₂ is used.

After the dry etching, using the resist removal apparatus of the present invention shown in FIG. 2, the resist mask 5 is removed. Here, the resist mask 5 is etched and removed by irradiation of a hydrogen radical 8. And, the MSQ film 4 having the formed via holes 7 is formed (FIG. 1C).

And, the via holes 7 of an inter-layer insulating film 9 composed of the silicon oxide film 3 and the MSQ film 4 is filled with a conductor material such as tungsten to form via plugs 10 and furthermore, wires 11 for connecting the via plugs 10 are formed by an alloy film of aluminum and copper.

Resist removal of the resist mask 5 in the present invention is executed by a resist removal apparatus 20 schematically shown in FIG. 2. FIG. 2 is a schematic cross sectional view of the resist removal apparatus of the present invention.

The resist removal apparatus 20 is a kind of the so-called remote plasma generation form in which the plasma generation unit and reaction chamber (processing chamber) are separated and as a basic structure thereof, includes, for example, a cylindrical processing chamber 21 composed of aluminum, whose surface is anodized, for executing resist removal, a rotary table 22 attached to the bottom inside the chamber 21, a gas transport pipe 23 which is an active species transport pipe attached to the upper part inside the chamber 21, a plasma generation unit 24, a gas feed system 29 of hydrogen or inactive gas (He, Ar, etc.), and an exhaust system 30 for ejecting processed gas after reaction from the chamber 21.

And, the plasma generation unit 24 has, for example, an anti-plasma member 26 installed on the inner wall of a discharge tube 25 composed of quartz glass and the discharge tube 25 is connected to a waveguide 28 for supplying a μ wave 27 (for example, a frequency of 2.45 GHz) into the discharge tube 25. Further, also on the inner wall of the gas transport pipe 23, the anti-plasma member 26 may be installed. Here, the anti-plasma member 26 is preferably composed of sapphire and it can be easily formed by depositing a sapphire film on the inner wall of the discharge tube 25 composed of quartz glass by chemical vapor deposition (CVD).

Next, the operation of the resist removal apparatus will be explained briefly. In the aforementioned removal of the resist mask 5 by the resist removal apparatus 20, a wafer 31 of a silicon substrate is loaded on the rotary table 22 and is rotated at a fixed speed. The rotation of the wafer 31 is executed to improve the uniformity of resist removal on the wafer surface. And, hydrogen mixed gas in which hydrogen gas is diluted by inactive gas is introduced into the discharge tube 25 from a gas introduction port 32, and the μ wave 27 generated by a magnetron is supplied into the discharge tube 25 via the waveguide 28, and the mixed gas is excited by plasma.

And, an active species of hydrogen is generated by this plasma excitation. Here, the active species of hydrogen includes protons and hydrogen molecular ions constituting hydrogen plasma and a neutral radical of hydrogen atoms or hydrogen molecules (referred to as a hydrogen radial as a whole). Among the active species, the hydrogen radical has a long life span, is introduced into the chamber 21 via the gas transport pipe 23, and removes the resist mask 5 on the surface of the wafer 31 loaded on the rotary table 22 as the hydrogen radical 8 explained in FIG. 1C. Further, a part of the hydrogen plasma is changed to a hydrogen radial during flowing through the gas transport pipe 23. And, the processed gas after resist removal is ejected from a gas ejection port 33 outside the chamber 21 by the exhaust system 30.

Here, the plasma excitation of mixed gas of hydrogen is executed by a microwave, so that the plasma density is increased, and the density of the hydrogen radical is also increased in correspondence to it, and the resist removal speed is increased. Further, by a substrate heating system 34 for heating the rotary table 22 and controlling the temperature, the temperature of the wafer 31 is set within the range from 200° C. to 400° C. Such a wafer temperature is within a high temperature range compared with a case that the conventional wafer temperature in resist removal by plasma is generally about 150° C. or lower. When a wafer temperature higher than that by the prior art is obtained like this, the resist removal speed is increased more.

By the removal method of the resist mask 5 using the aforementioned resist removal apparatus, the specific dielectric constant of an inter-layer insulating film after resist removal can be kept low straight. For example, a case that the porous MSQ film 4 of a specific dielectric constant of 2.0 is used to form the inter-layer insulating film explained in FIG. 1 is compared with a case of the prior art, and the results are shown in Table 1. The specific dielectric constants are calculated from the capacity values of the capacitor measured at 1 MHz. Here, in the prior art, resists are removed by plasma obtained by the capacitive coupling type plasma generation method as shown in Patent Document 1. Further, also in this case, the raw gas for resist removal is diluted hydrogen gas similar to that of the present invention.

TABLE 1

| | Present invention | Prior art |
|---|---|---|
| Increase rate of specific | <1% | >50% |
| dielectric constant | | |

In the case of the prior art, the specific dielectric constant of the MSQ film after resist removal is 3 or more and the increase rate of the specific dielectric constant is 50% or higher, while in this embodiment, the specific dielectric constant of the MSQ film after resist removal is little changed such as 2. After subject to the resist removal process, the aforementioned capacity value of the capacitor is apt to slightly increase, though even in consideration of measurement errors, the increase rate of the specific dielectric constant is 1% or less.

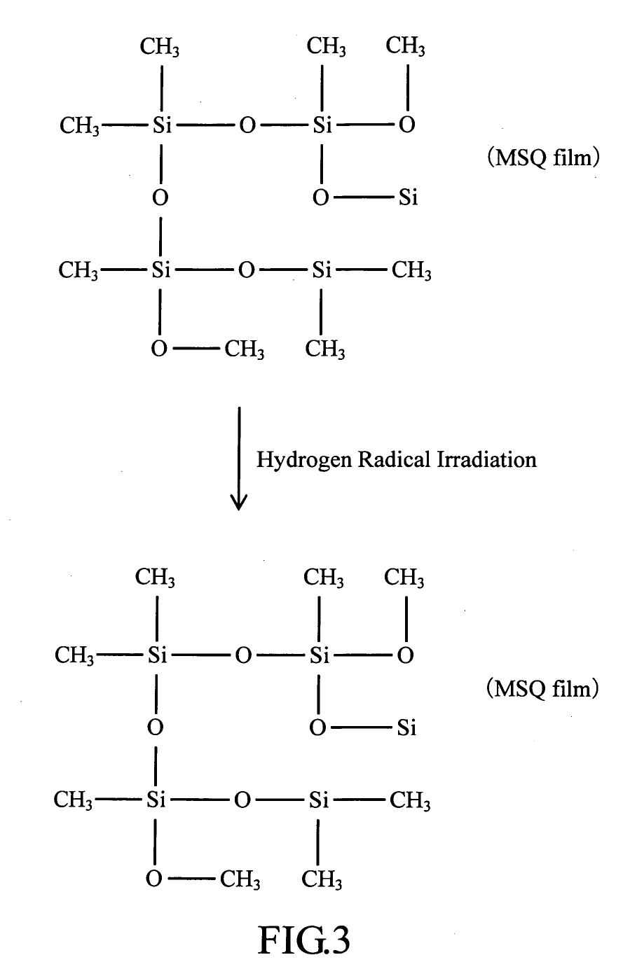

In this embodiment, the reason that the specific dielectric constant of the MSQ film is little changed is that as shown in FIG. 3, even if the MSQ film is irradiated with the hydrogen radical in resist removal, the methyl ground (—CH3) remains as it is and the film quality is little changed. Here, FIG. 3 is a schematic structural diagram of the MSQ film with reference to measured results of XPS (X-ray photoelectron spectroscopy).

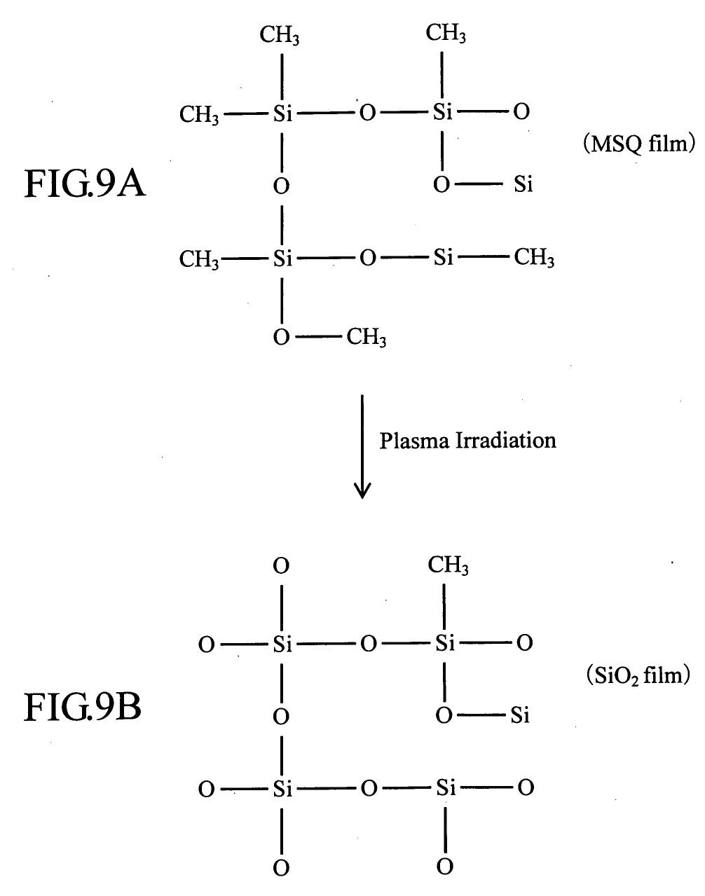

On the other hand, in the case of resist removal by plasma by the prior art, the plasma generation unit and wafer on the processed substrate are in the same chamber, and hydrogen plasma generated by plasma excitation is directly irradiated onto the MSQ film, so that the MSQ film is deteriorated in the quality including the porosity. Furthermore, in resist removal by plasma, the inner wall of the chamber is sputtered by hydrogen gas diluted by inactive gas, and an active species, though a very small amount, of a strong oxidative effect such as oxygen ions or an oxygen radical is generated and the active species, exactly similarly to the explanation in FIG. 9A-9B, changes the bond of Si—CH3 to the bond of Si—O. In the case of the prior art, it seems that by the aforementioned deterioration of the MSQ film, the specific dielectric constant of the film is increased.

As mentioned above, the characteristic of this embodiment is that when the insulating film of a low dielectric constant is used for an inter-layer insulating film, in removal of the resist mask used for the processing thereof, gas containing hydrogen is generated by remote plasma and the resist is removed by the hydrogen radical.

In the first embodiment, the dielectric constant of the insulating film of a low dielectric constant after resist removal is not increased. And, in the wiring structure of the semiconductor device, an inter-layer insulating film of a low dielectric constant can be formed simply and highly accurately under high reproducibility. Further, the reduction in the resist removal speed is improved greatly and the resist removal method in the first embodiment can be applied sufficiently to manufacture of semiconductor devices. In this way, in the semiconductor device, a wiring structure of a specific dielectric constant of 3 or less and a small parasitic capacity can be easily formed and practical realization of a highly efficient semiconductor device capable of operating at high speed is promoted.

### Embodiment 2

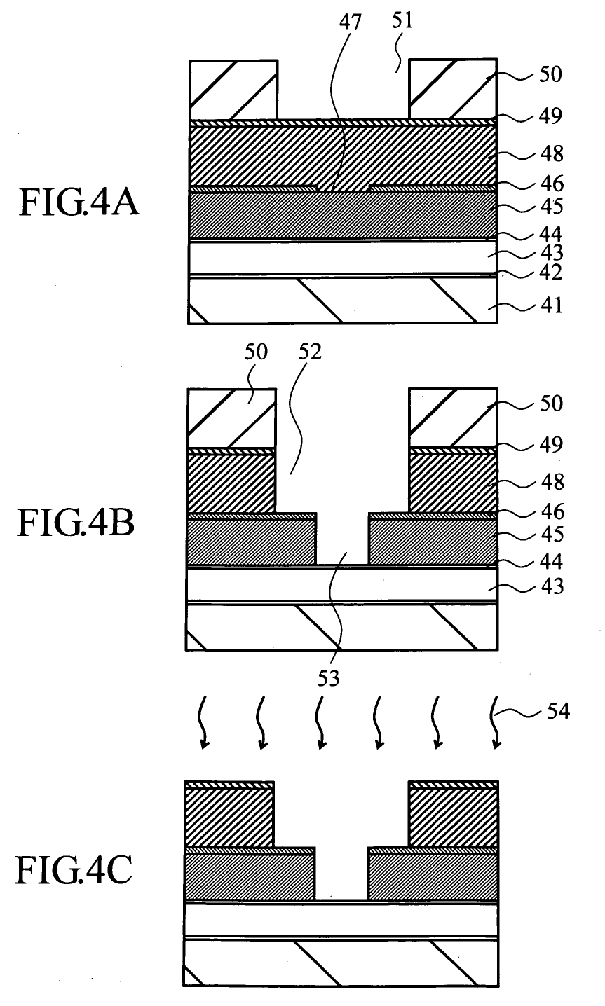

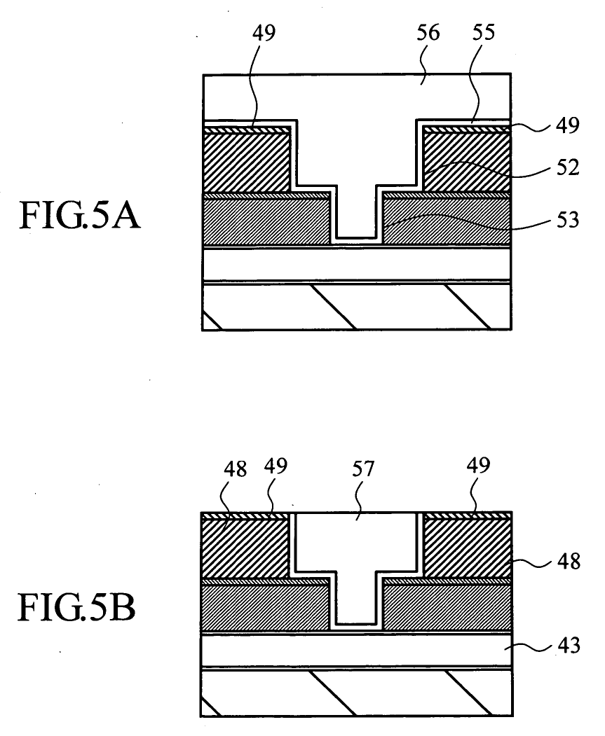

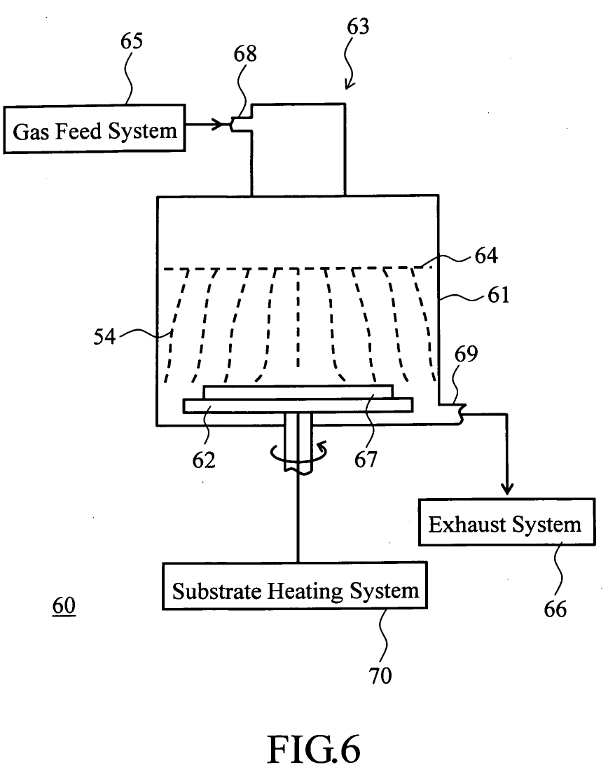

FIGS. 4A-4C and 5A-5B is cross sectional views of devices for each step showing manufacture of a semiconductor device to which the resist removal method relating to the second embodiment of the present invention is applied. And, FIG. 6 is a schematic cross sectional view of another resist removal apparatus used for the aforementioned resist removal.

On a silicon substrate (not shown in the drawing), a lower layer insulating film 41 composed of a silicon oxide film is formed and on the lower layer insulating film 41, using a titanium series conductor material, a first barrier layer 42, a lower layer wire 43 of an alloy film of aluminum and copper, and a second barrier layer 44 are formed in a laminated structure. And, a coating solution becoming an MSQ film is coated overall the structure by the spin-on coating method, and then it is calcined, for example, at about 150° C. and furthermore is heat-treated at about 400° C. in a diffusion oven, thus a first MSQ film 45 with a thickness of about 500 nm is formed. Then, on the surface of the first MSQ film 45, a first protective insulating film 46 composed of a silicon carbide film (SiC film) with a thickness of 50 nm is formed, and at a part thereof, an opening 47 is formed by selective etching. And, using the spin-on coating method, a second MSQ film 48 with a thickness of about 1 μm and a second protective insulating film 49 composed of a SiC film with a thickness of 50 nm are laminated and formed, and by the photolithographic art, a resist mask 50 is formed on the second protective insulating film 49. Here, on the resist mask 50, a resist opening 51 is formed (FIG. 4A).

Next, the resist mask 50 is used as an etching mask, and firstly the second protective insulating film 49 is etched by the RIE by plasma excitation of N2 gas, and then the second MSQ film 48 is etched by the RIE by plasma excitation of mixed gas of C3F8 gas, O2 gas, and Ar gas, and furthermore using the first protective insulating film 46 as an etching stopper, the first MSQ film 45 under the opening 47 is dry-etched. By doing this, a wiring trench 52 is formed in the second MSQ film 48 and the second protective insulating film and a via hole 53 is formed in the first MSQ film 45 and the first protective insulating film 46 (FIG. 4B).

After the aforementioned continuous dry etching, using the resist removal apparatus of the present invention shown in FIG. 6, the resist mask 50 is removed. Here, the resist mask 50 is etched and removed mainly by irradiation of hydrogen radical 54 (FIG. 4C).

Next, on the inner walls of the wiring trench 52 and the via hole 53 and the surface of the second protective insulating film 49, a third barrier layer 55 is formed, for example, by a tantalum nitride (TaN) film with a thickness of about 20 nm. And, a Cu film 56 with a thickness of about 1 μm is formed by the known plating method (FIG. 5A).

And, using the known chemical mechanical polishing (CMP) method, the unnecessary Cu film 56 and the third barrier layer 55 on the second protective insulating film 49 are polished and removed. At the CMP step, the second protective insulating film 49 functions as a stopper film for CMP and protects the second MSQ film 48 from CMP. In this way, a dual damascene wire connected to the lower layer wire 43 is formed (FIG. 5B).

Resist removal of the resist mask 50 in this embodiment is executed using a resist removal apparatus 60 as schematically shown in FIG. 6. The resist removal apparatus 60 is characterized in that a plasma shielding plate is inserted between the plasma generation unit and a wafer which is a processed substrate and as a basic structure thereof, includes, for example, a cylindrical processing chamber 61 composed of aluminum whose surface is anodized, a rotary table 62 attached to the bottom inside the chamber 61, a plasma generation unit 64 attached to the upper part inside the chamber 61, a plasma shielding plate between the rotary table 62 and the plasma generation unit 64, a gas feed system 65 of hydrogen or inactive gas, and an exhaust system 66 for ejecting processed gas after reaction from the chamber 61.

Here, the plasma shielding plate 64 is composed of a perforated plate made of aluminum or SUS and is attached inside the chamber 61 in the floating state. And, to the plasma generation unit 63, apparatus such as a helicon wave plasma source, an ECR (electron cyclotron resonance) plasma source, and an ICP (inductively coupled plasma) source are attached so as to generate high density plasma (HDP). Further, as explained in the first embodiment, the inner wall of the plasma generation chamber of the plasma generation unit 63 is preferably coated with an anti-plasma member of a material such as sapphire.

Next, the operation of the resist removal apparatus will be explained briefly. In the removal of the resist mask 50 by the resist removal apparatus 60, as explained in FIG. 2, a wafer 47 is loaded on the rotary table 62 and is rotated at a fixed speed. And, hydrogen mixed gas is introduced into the plasma generation unit 63 through a gas introduction port 68, and the mixed gas is excited by plasma by the aforementioned high density plasma generation source, and a large amount of an active species of hydrogen is generated. The active species of hydrogen formed in this wary is diffused in the chamber 61, though protons and hydrogen molecular ions constituting the hydrogen plasma among the active species are cut by the plasma shielding plate 64, and the hydrogen radical 54 explained in FIG. 4(c) removes the resist mask 50 on the surface of the wafer 67. And, the processed gas after resist removal is ejected from the chamber 61 through a gas ejection port 69 by the exhaust system 66.

Also in this case, the hydrogen radical density becomes very high and the resist removal speed is increased. And, by a substrate heating system 70 for heating the rotary table 62 and controlling the temperature, the temperature of the wafer 67 is set to a high temperature between 200° C. and 400° C., so that the resist removal speed is increased more.

Further, by the removal method of the resist mask 50 using the resist removal apparatus, as explained in the first embodiment, the specific dielectric constant of the inter-layer insulating film after resist removal can be kept low straight. For example, in the inter-layer insulating film in the dual damascene wiring structure explained in FIGS. 4A-4C and 5A-5B, when a porous MSQ film of a specific dielectric constant of 2.5 is used, the specific dielectric constant thereof after resist removal is kept at 2.5 straight.

As mentioned above, the characteristic of the second embodiment is that when the insulating film of a low dielectric constant is used for an inter-layer insulating film, in removal of the resist mask used for the processing thereof, plasma of gas including hydrogen is prevented from irradiating on the wafer by the plasma shielding plate and the resist is removed.

In the second embodiment, the perfect remote plasma generation method as used in the first embodiment is not used and in resist removal, hydrogen ions are partially irradiated on the wafer. And, an oxygen active species generated by sputtering of the ions is irradiated on the wafer. However, in this embodiment, the insulating film surface of a low dielectric constant containing an organic component is covered with a protective insulating film of a high hydrogen plasma resistance or a high oxygen active species resistance such as SiC, so that the dielectric constant of the insulating film of a low dielectric constant after resist removal is little increased. And, in this case, an effect is produced that the resist removal speed is increased higher than that in the first embodiment. It is realized by an effect of generation of hydrogen ions or the oxygen active species. The resist removal method in this embodiment can be sufficiently applied to manufacture of semiconductor devices. And, also in this case, in the semiconductor device, a (dual) damascene wiring structure of a small parasitic capacity can be easily formed using an inter-layer insulating film of a specific dielectric constant of 3 or less and practical realization of a highly efficient semiconductor device capable of operating at high speed is promoted.

The embodiments of the present invention are described in detail above by referring to the drawings. However, the concrete constitution is not limited to the embodiments and within a range which is not deviated from the object of the present invention, changes of the design are included in the present invention. In the aforementioned embodiments, as a representative example of the insulating film of the siloxane skeleton containing an organic component which is an insulating film of a low dielectric constant, the case that the MSQ film is dry-etched and the inter-layer insulating film used for the wiring structure is formed is explained. However, to a case that using an insulating film of the silsesquioxane group other than it or an inorganic insulating film such as an SiOC film, an inter-layer insulating film of a semiconductor device is formed, the present invention can be applied exactly similarly. And, the present invention, to a case that using an insulating film of a low dielectric constant having a main skeleton of organic high polymer molecules, an inter-layer insulating film is formed, can be applied more effectively.

And, the present invention, also to a case that when an alloy film of aluminum and copper is dry-etched using a resist mask and wires are formed on an inter-layer insulating film composed of an insulating film of a low dielectric constant, the resist mask is removed, can be applied similarly.

Furthermore, the present invention, also to a case that a resist mask used when impurity ions are injected into a silicon substrate via an inter-layer insulating film using an insulating film of a low dielectric constant is removed, can be applied exactly similarly. Such a resist mask used for injection of impurity ions is frequently used to manufacture semiconductor devices loading a ROM (the multilevel function included) composed of one MOSFET.

Furthermore, the present invention, in addition to the case that a semiconductor device is formed on a silicon substrate, can be applied similarly to a case that a semiconductor device is formed on a compound semiconductor substrate such as a GaAs substrate or a GaN substrate. And, the present invention can be applied also to a case that an insulating material such as prepreg of a multi-layer circuit board used to mount a semiconductor device. As mentioned above, the present invention is not limited to the aforementioned embodiments and within the range of technical ideas of the present invention, the embodiments may be properly modified.

According to the aforementioned embodiments of the present invention, by the resist removal method using hydrogen gas of the present invention, an inter-layer insulating film of a low dielectric constant used for the wiring structure of a semiconductor device can be formed simply and highly accurately under high reproducibility. And, in the resist removal using hydrogen gas, the resist removal speed is increased and the aforementioned resist removal method can be applied to manufacture of semiconductor devices.

1. A resist removal method for etching a resist film on a processed substrate using a hydrogen active species generated by plasma excitation of raw gas including hydrogen gas, comprising the step of:
using a resist removal apparatus including a plasma generation unit of said hydrogen gas, a processing chamber separated and installed so as to prevent hydrogen plasma generated by said plasma generation unit from irradiating said processed substrate, and an active species transport pipe for transporting said hydrogen active species generated by said plasma generation unit to said processing chamber and removing by etching said resist film formed on said processed substrate using mixed gas of hydrogen gas and inactive gas as said raw gas.

2. A resist removal method according to claim 1, wherein an inner wall of a part of said plasma generation unit in contact with said plasma is formed by an anti-plasma member including sapphire.

3. A resist removal method according to claim 1, wherein said plasma excitation is executed by using a microwave, a helicon wave, or a high frequency wave.

4. A resist removal method according to claim 1, wherein a temperature of said processed substrate is set within a range from 200° C. to 400° C. and said resist film formed on said processed substrate is removed by etching.

5. A resist removal method according to claim 1, wherein said resist film is a resist mask used for patterning an insulating film of a low dielectric constant of a specific dielectric constant of 3 or less formed on said processed substrate.

6. A resist removal method for etching a resist film on a processed substrate using a hydrogen active species generated by plasma excitation of raw gas including hydrogen gas, comprising the step of:
using a resist removal apparatus including a plasma generation unit of said hydrogen gas, a processing chamber for loading said processed substrate installed in an integral structure with said plasma generation unit, and a shielding plate inserted between said plasma generation unit and said processed substrate so as to shield hydrogen plasma generated in said plasma generation unit and removing by etching said resist film formed on said processed substrate using mixed gas of hydrogen gas and inactive gas as said raw gas.

7. A resist removal method according to claim 6, wherein an inner wall of a part of said plasma generation unit in contact with said plasma is formed by an anti-plasma member including sapphire.

8. A resist removal method according to claim 6, wherein said plasma excitation is executed by using a microwave, a helicon wave, or a high frequency wave.

9. A resist removal method according to claim 6, wherein a temperature of said processed substrate is set within a range from 200° C. to 400° C. and said resist film formed on said processed substrate is removed by etching.

10. A resist removal method according to claim 6, wherein said resist film is a resist mask used for patterning an insulating film of a low dielectric constant of a specific dielectric constant of 3 or less formed on said processed substrate.

11. A semiconductor device manufactured by etching a resist film used for pattrning an insulating film of a low dielectric constant of a specific dielectric constant of 3 or less formed on a processed substrate using a hydrogen active species generated by exciting raw gas including mixed gas of hydrogen gas and inactive gas by plasma, wherein:
said insulating film of a low dielectric constant is an inter-layer insulating film of a multi-layer wiring structure for connecting between semiconductor device elements.

12. A semiconductor device according to claim 11, wherein said inter-layer insulating film is an inter-layer insulating film of a damascene wiring structure for connecting between semiconductor device elements.

13. A semiconductor device according to claim 11, wherein said hydrogen active species, by an apparatus including a plasma generation unit of hydrogen gas and a processing chamber separated and installed so as to prevent hydrogen plasma generated by said plasma generation unit from irradiating said processed substrate, is separated from said hydrogen plasma.

14. A semiconductor device according to claim 11, wherein said hydrogen active species, by an apparatus including a plasma generation unit of hydrogen gas, a processing chamber for loading said processed substrate installed in an integral structure with said plasma generation unit, and a shielding plate inserted between said plasma generation unit and said processed substrate so as to shield hydrogen plasma generated in said plasma generation unit, is separated from said hydrogen plasma.
